(19) United States
(12) Patent Application Publication
(10) Pub. No.: US 2010/0008219 A1
(43) Pub. Date: Jan. 14, 2010

(54) Automatic network signal diversion mechanism

(75) Inventor: Po-Jung Chen, Taoyuan City (TW)

Correspondence Address: BACON & THOMAS, PLLC, 625 SLATERS LANE, FOURTH FLOOR, ALEXANDRIA, VA, 22314-1176, US

(73) Assignee: U.D. ELECTRONIC CORP., Taoyuan City (TW)

(21) Appl. No.: 12/216,937

(22) Filed: Jul. 14, 2008

(51) Int. Cl. G01R 31/08

(52) U.S. Cl. 370/216

(57) ABSTRACT

The present invention provides an automatic network signal diversion mechanism capable of preventing interruptions of power supply and signals, which comprises an electronic device, at least one filter module and an automatic diversion device. The electronic device has a circuit board mounted with a plurality of electronic components, the filter module, the automatic diversion device and a circuit layout, and equipped with at least one signal input port and signal output port connected electrically with the filter module and the automatic diversion device. The filter module is electrically connected with a data processing unit on a motherboard of a computer host to enable filtering of external network signals, and the automatic diversion device is electrically connected with a power input device. When the power input device fails, a signal diversion component of the automatic diversion device will be in a closed-circuit connection status for allowing external network signals to be inputted from the signal input port and directly diverted and outputted to the signal output port, so as to avoid interruptions of power supply or signals for the electronic device that may occur as a result of short circuits, cut-off or failure of the power input device.

### BACKGROUND OF THE INVENTION

1. Field of the Invention

The present invention provides an automatic network signal diversion mechanism capable of preventing interruptions of power supply and signals, particularly, the mechanism allowing the external network signals inputted from a signal input port to be directly diverted and transmitted to a signal output port for output without being converted by a control chip installed on a motherboard of a computer host, in order to prevent failures in power supply or signals of an electronic device from occurring as a result of short circuit, outage or failure of a power input device.

2. Description of the Related Art

Nowadays with rapid developments in computer technology, desktop or notebook computers have prevailed in every corner of our society, and the development trends of computers will also towards high computational performance, rapid processing speed and miniaturization. Moreover, as network communication technologies develop rapidly and vigorously, people are bring into another new life, study, work and leisure that has never seen before, and it is possible for the people to deliver real-time information, advertisements, or to send and receive e-mails, etc. via network communication for interaction and contact between them. At the same time, networks can be used to search for various kinds of information, enable real-time Internet communication or play online games for entertainment, thus forming a closer and more integral relationship between people and networks.

Generally, networks can be classified into such types as Local Area Network (LAN), Metropolitan Area Network (MAN), Wide Area Network (WAN) and Wireless Network and Internet, depending on geographical coverage of computers. Among these kinds of networks, the LAN is a kind of networks consisting of many independent computers that are interlinked and possibly located in different offices in the same building, or in different buildings in the same company or school. Common standards for the LAN include IEEE802.3 Ethernet, Fast Ethernet and Gigabit Ethernet, etc, in which a bridge is used to connect different network segments. In addition, the LAN architecture is adopted mainly to facilitate sharing of equipments and resources inside offices, companies or schools with extendable applications in synchronous database processing operations to achieve best results from resource applications.

Besides, the LAN can be connected to the WAN via a connection interface. In such way, the WAN can link a variety of independent computers located in different cities, countries or even continents together, as shown in FIG. 7, which is a schematic diagram of network architecture according to a prior art. Referring to FIG. 7, an equipment A is equipped with a router or a hub, which can be used to build a LAN by interconnecting at least one computer. At the same time, the equipment A is used to convert WAN signals into LAN signals, which will be further transmitted to an equipments B and C for use, and to enable many independent computers to interconnect or share resource through Internet. However, when the power supply to the router or hub in the equipment A is cut off, it is impossible for the WAN signals to be converted into the LAN signals. As a result, the equipments B and C cannot be interconnected or communicate with external networks.

Therefore, usually in the process of building networks, a signal conversion device is pre-installed at the front end of the equipments B and C to make the WAN signals be directly transmitted to the equipments B and C for use through the signal conversion device without being converted into the LAN signals through the equipment A when the power supply to the equipment A fails, thus ensuring the signal connections of the whole network will not be interrupted. Referring to FIGS. 8 and 9, automatic switch components are placed at back ends of network ports A and B. When the power supply is in normal, the WAN signals will be first inputted from the network port A for filtering by a transformer, and the filtered signals will be converted into the LAN signals by an IC chip (PHY IC Chip) and then outputted through the filter and the network port B; if there is power outage at this time, the automatic switch component will begin to work and cause short-circuit between the network port A and the network port B, allowing the WAN signals to be transmitted directly to the network port B for output via the automatic switch component. Because the WAN signals will not be converted by the IC chip in the process of transmission, the signals will not be impacted by the power supply to the IC chip, thus achieving the goal of uninterrupted transmission of network signals. However, the prior art still has problems and disadvantages as follows:

1. The network ports A and B, the automatic switch component, the filter and the IC chip are installed on the motherboard independently. Because the decrease in the space inside the electronic equipments and many electronic components arranged on the motherboard, these electronic components are installed more densely. As a result, the network signals will generate various kinds of electromagnetic interferences in the process of transmission, conversion or filtering, thus causing an increase in electromagnetic interferences on the motherboard, too. This will have negative impact on the quality of signal transmission, and may even result in interruption or failure of signal transmission in some cases.

2. Nowadays as the computer hosts or servers tend to be light, thin, short and small in size, how to reduce the size of these equipments effectively seems to become one of the most essential factors in design. However, the connection interfaces of motherboards inside the computer hosts now have been insufficient to accommodate an increasing number of peripheral devices and due to miniaturization of the motherboards, electronic components related to the peripheral devices on the motherboards are required to be repositioned into the peripheral devices. In such cases, if the motherboards are added with the automatic switch components, which will occupy some space, it not only is difficult to arrange the electronic components on the motherboards as expected, but also makes overall design too disorderly and make it difficult to reduce the size of the motherboards, and will also lead to considerable increase in production costs.

Therefore, it is desirable to provide an automatic network signal diversion mechanism that eliminates the aforesaid problems.

### SUMMARY OF THE INVENTION

The, present invention has been accomplished under the circumstances in view. The primary objective of the present invention to provide at least one signal input port and signal output port in an electronic device, that are electrically connected to an automatic diverting device to form a signal diversion loop, and the automatic diversion device is electrically connected with a power input device. If the power input device fails, a signal diversion component of the automatic diversion device will be kept in a closed-circuit connection status, allowing external network signals to be inputted from the signal input port and outputted directly via the signal output port without being converted through a control chip in a computer host. In this way, the external network signals can be diverted and outputted immediately before interruption of the signals, thus preventing paralysis of the whole network system caused by signal interruption and enabling the network system to operate continuously and normally even if the power supply to the electronic device is cut off.

The secondary objective of the present invention is to integrate the signal input port, the signal output port, a filter module and the automatic diversion device into the electronic device. Such integration requires less space for the components on the motherboard of the computer host than that the components independently preset on the motherboard of the computer host, requires less number of components and reduces the cost. In addition, it allows the original automatic diversion device installed on the motherboard to be removed, helps simplify the layout of the control circuit, connection interfaces and electronic components on the motherboard, and helps reduce the space for circuit layout effectively.

Another objective of the present invention is that the electronic device is covered by a shield shell, which is connected with the motherboard of the computer host to form a grounding loop. The shield shell can be utilized to make electromagnetic interferes generated around the electronic device and the noise on the circuit board be inducted and transmitted into the grounding end of the computer host for release, thus effectively preventing the problem of interference that may result from electromagnetic waves.

### BRIEF DESCRIPTION OF THE DRAWINGS

FIG. 1 is a block diagram of one preferred embodiment of the present invention.

FIG. 2 shows a circuit diagram of one preferred embodiment of the present invention.

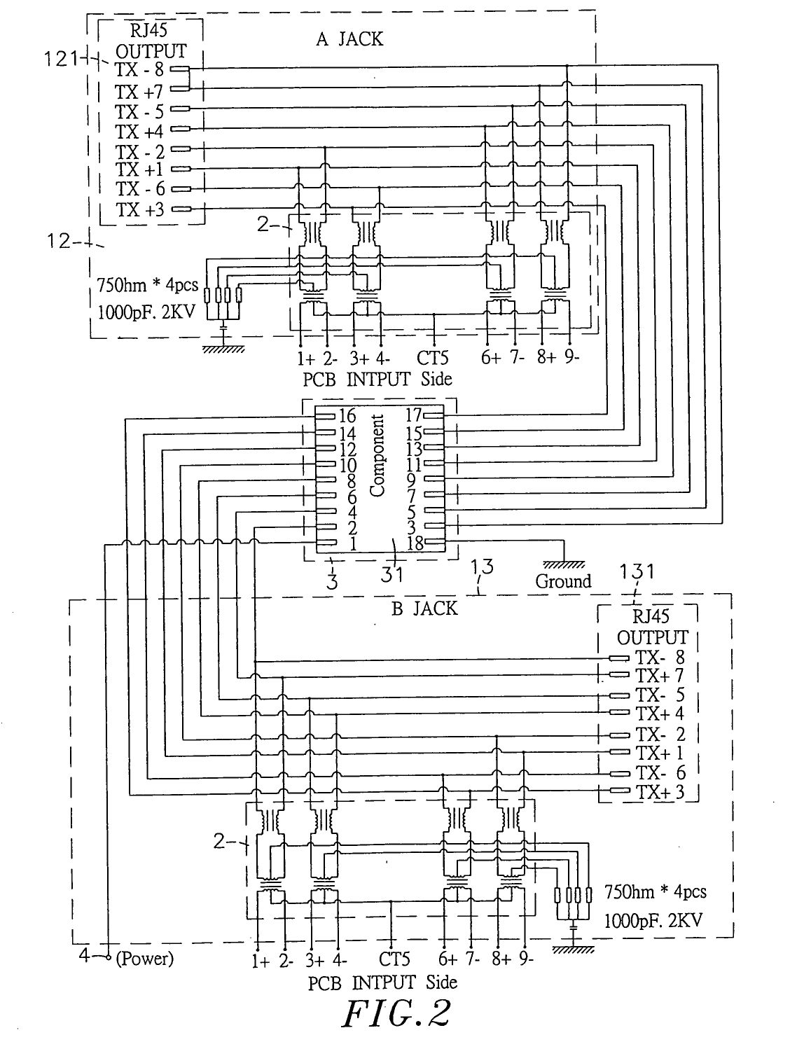

FIG. 3 is a appearance diagram of one preferred embodiment of the present invention.

FIG. 4 is a partial lateral section drawing of one preferred embodiment of the present invention.

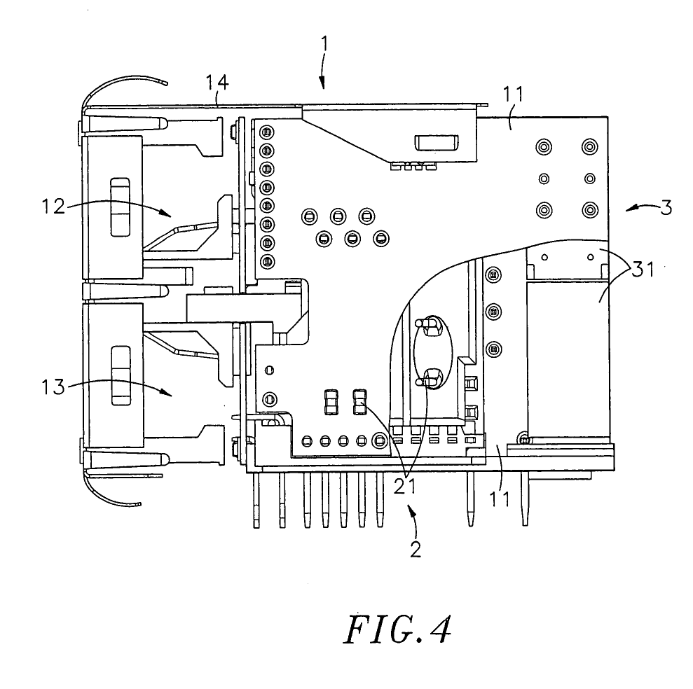

FIG. 5 is a front-view diagram of another preferred embodiment of the present invention.

FIG. 6 shows a front-view diagram of a second preferred embodiment of the present invention.

FIG. 7 is a schematic diagram of network architecture according to a prior art.

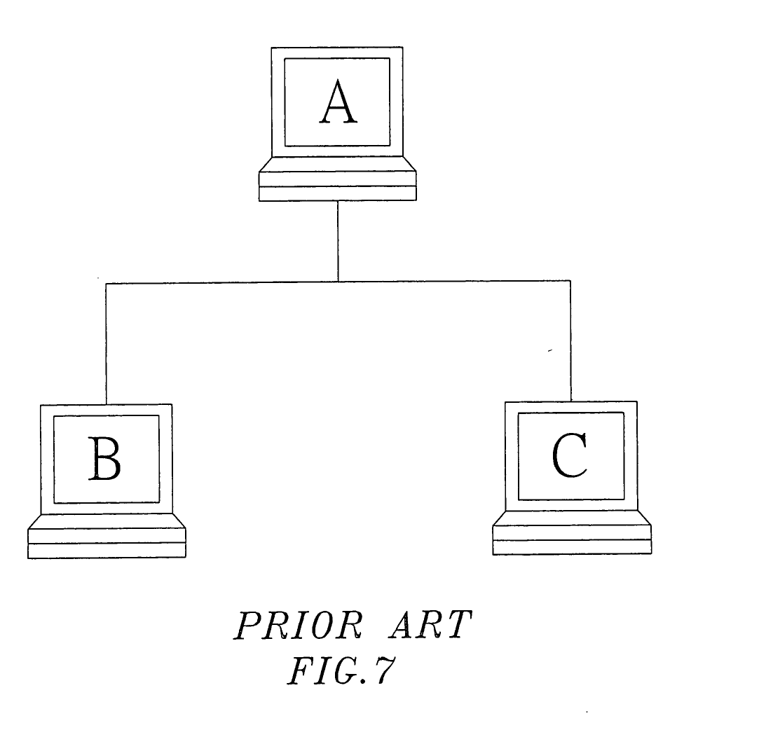

FIG. 8 is a schematic diagram of an automatic diversion device according to the prior art.

FIG. 9 is a schematic diagram of another automatic diversion device according to another prior art.

### DETAILED DESCRIPTION OF THE PREFERRED EMBODIMENT

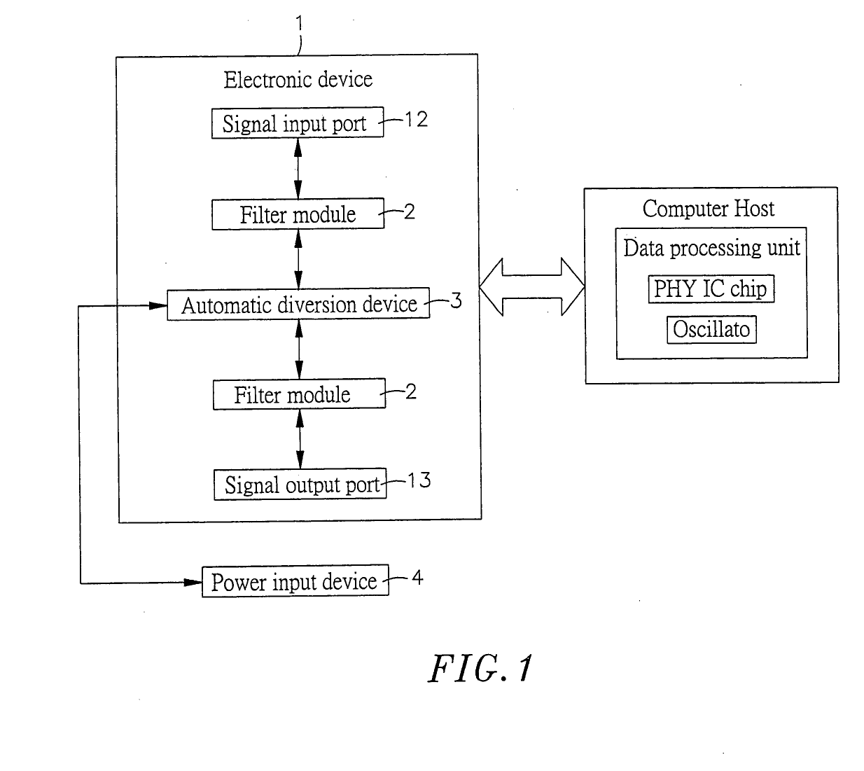

Referring to FIGS. 1˜4, an automatic network signal diversion mechanism capable of preventing interruptions of power supply and signals of the present invention comprises an electronic device 1, at least one filter module 2 and an automatic diversion device 3.

The electronic device 1 comprises a circuit board 11 mounted with a plurality of electronic components, the filter module 2, the automatic diversion device 3 and a circuit layout thereon. The circuit board 11 has at least one signal input port 12 and signal output port 13, both of which are equipped with a plurality of connection terminals 121 and 131 within them. Besides, the electronic device 1 is covered with a shield shell 14, which is connected with a motherboard in a computer host (not shown in the figures) to form a grounding loop, so that electromagnetic interferences generated around the electronic device 1 and the noise on the circuit board 11 can be inducted and transmitted into the grounding end of the computer host for release.

The filter module 2 is electrically connected with the signal input port 12 and the signal output port 13 of the electronic device 1 respectively, and may comprise a resistor, a capacitor or other passive components and a transformer 21. Moreover, the filter module 2 can be connected electrically with a data processing unit on the motherboard of the computer host to allow external network signals to be transmitted to the data processing unit for communication and processing after the filtering of signal noise is implemented. Besides, the data processing unit at least comprises an Ethernet control chip (PHY IC Chip) and an oscillator, therefore, the control chip built-in in the data processing unit can be used to convert external network WAN signals inputted from the signal input port 12 into LAN signals, and then output the LAN signals via the signal output port 13.

The automatic diversion device 3 installed on the circuit board 11 of the electronic device 1 is connected electrically with the signal input port 12 and the signal output port 13 respectively, and comprises a signal diversion component 31 which may be a relay, signal switcher or other electronic component with input/output control functions. And the automatic diversion device 3 is connected electrically with a power input device 4 for providing the needed electricity to the electronic device 1. The power input device 4 may be represented by a power source or battery on the motherboard of the computer host, or even an uninterruptible power supply (UPS) or battery that are not installed inside.

When in use, the user can insert a signal transmission cable compatible with a certain type into the signal input port 12 of the electronic device 1 and connect electrically with the connection terminals 121 of the signal input port 12. In this way, the external network WAN signals can be transmitted to the circuit board 11 from the signal input port 12 and be filtered by the transformer 21 of the filter module 2 in order to filter the noise and keep the useful WAN signals. Then, the WAN signals are further transmitted to the data processing unit on the motherboard of the computer host, allowing the control chip built-in the data processing unit to convert the WAN signals into the LAN signals. Then, the wave filter 21 of the filter module 2 also carries out filtering to the LAN signals in the same way, and the useful LAN signals are transmitted to the signal output port 13 for output. Because the signal output port 13 can also be connected with the signal transmission cable with a certain type, the LAN signals are outputted via the signal transmission cable.

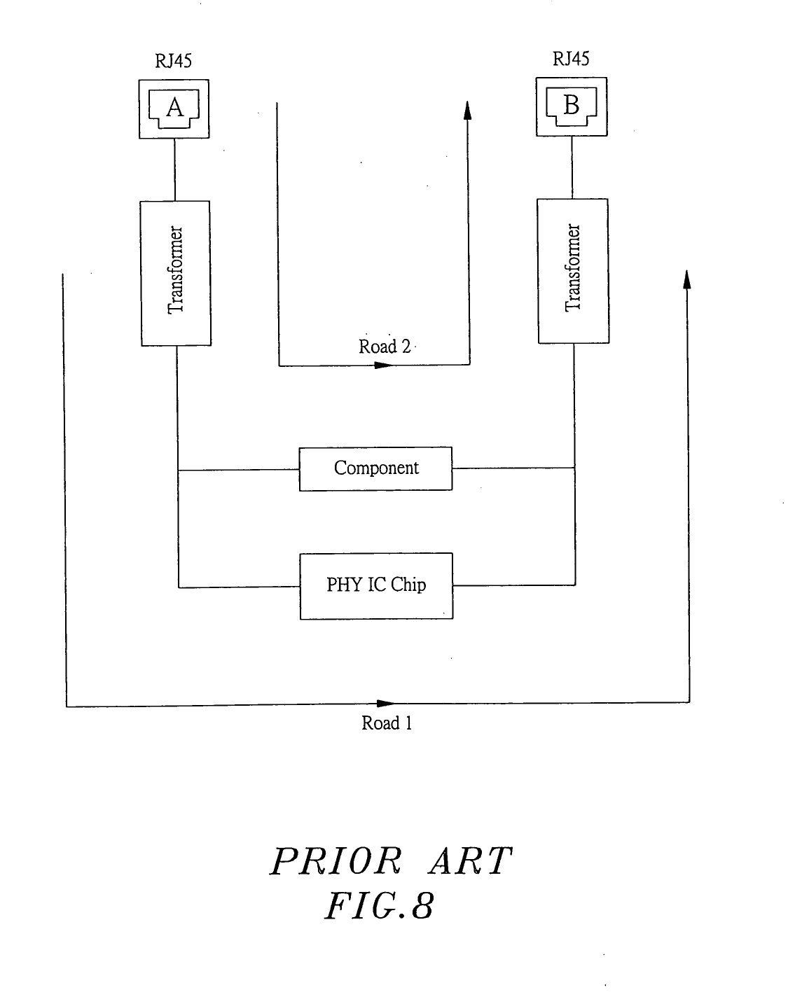

Referring to FIGS. 8˜9 and 2 again, the electronic device 1 of the present invention comprises the automatic diversion device 3, which is electrically connected with the signal input port 12 and the signal output port 13 respectively to form a signal diversion loop. The signal diversion component 31 of the automatic diversion device 3 comprises a plurality of pins (Pin1˜Pin18), and one of pin (Pin1) can be connected electrically with the power input device 4 for providing the needed electricity to the electronic device 1. Therefore, when the power input device 4 works normally, the plurality of pins of the signal diversion component 31 (Pin 2&3, Pin 4&5 . . . Pin 16&17) will be in the status of open-circuit disconnection. At this time, the external network WAN signals will be inputted from the connection terminals 121 (Input +1, −2˜−8) of the signal input port 12, converted into the LAN signals in the same process as stated above, and then transmitted to the connection terminals 131 (Output +1, −2˜−8) of the signal output port 13 for output (as shown in Road 1 of the figure); yet when the power input device 4 fails, the plurality of pins of the signal diversion component 31 (Pin 2&3, Pin 4&5 . . . Pin 16&17) will be in the status of close-circuit connection, allowing the external network WAN signals to be inputted from the connection terminals 121 (Input +1, −2˜−8) of the signal input port 12 and directly transmitted to the connection terminals 131 (Output +1, −2˜−8) of the signal output port 13 for output (as shown in Road 2 of the figure) instead of being transmitted to the motherboard of the computer host for the control chip built-in the data processing unit to convert into the LAN signals. Such structural design can avoid failures of the electronic device 1 in interruptions of power supply or signals due to short circuit, outage or failure of the power input device 4.

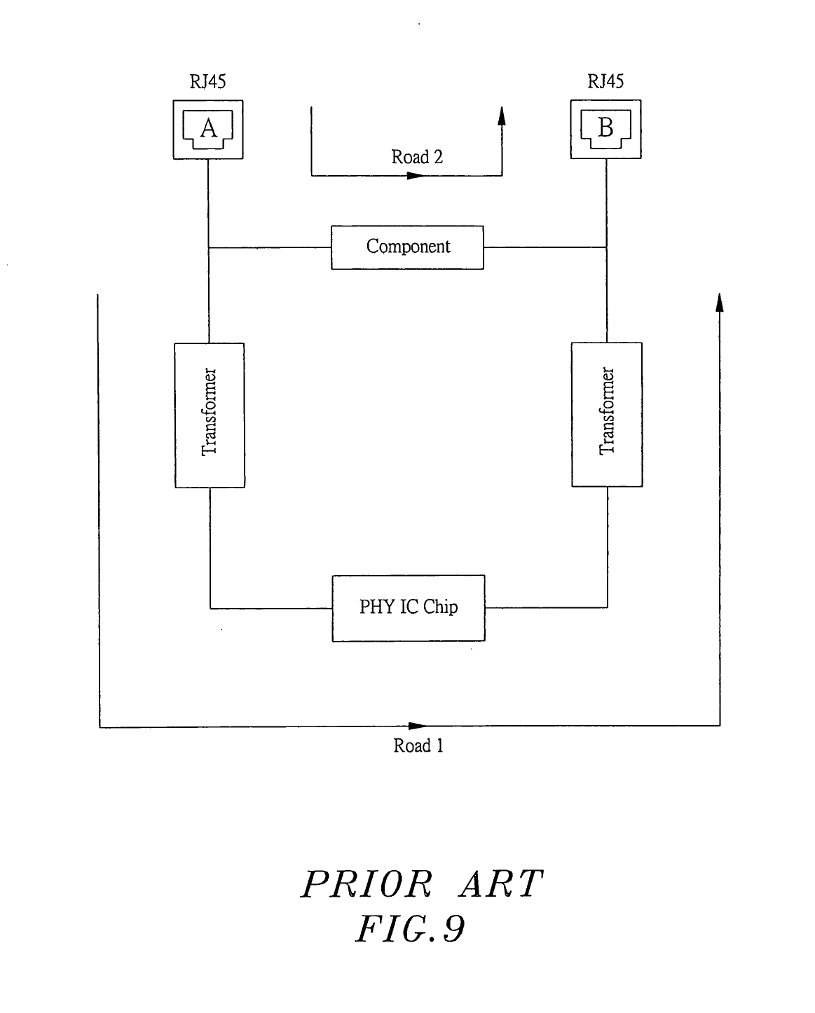

As indicated above, the embodiment of the present invention is described mainly by giving an example in which the automatic diversion device 3 is connected and used in parallel with the transformer 21 of the filter module 2 and the control chip (PHY IC Chip) on the motherboard of the computer host. However, in practice, the applications of the present invention are not limited to connections in parallel or in series. Besides, in addition to install the signal diversion component 31 of the automatic diversion device 3 between the transformer 21 and the control chip (as shown in FIG. 8), the signal diversion component 31 can also be placed between the transformer 21 and the signal input port 12 and the signal output port 13 of the electronic device 1 (as shown in FIG. 9). Thus, when the power input device 4 fails, the external network WAN signals, after being inputted from the signal input port 12, will be directly diverted by the automatic diversion device 3 and transmitted to the signal output port 13 for output without being filtered by the filter module 2, resulting in effective reduction of the WAN signal attenuations and securing more stable and precise transmission of signals in the process of network signal transmission.

Furthermore, the signal input port 12, the signal output port 13, the filter module 2 and the automatic diversion device 3 are integrated into the electronic device 1. Such integration occupies less space in the motherboard than that the components independently installed in the motherboard of the computer host, requires less number of components and reduces the cost. In addition, the integration allows the original automatic diversion device 3 installed in the motherboard to be removed, helps simplify the control circuit layout, connection interfaces and electronic components in the motherboard, and helps reduce the space for circuit layout effectively. Besides, because the space inside the computer host reduces, the electronic components installed on the motherboard are more densely, resulting in production of various electromagnetic interferences in the process of transmission, conversion or filtering of the external network signals. Therefore, the electronic device 1 of the present invention is covered with the shield shell 14 and connected with the motherboard of the computer host to form a grounding loop so as to induct and transmit the electromagnetic interferences generated around the electronic device 1 and the noises on the circuit board 11 into the grounding end of the computer host for release, thus effectively preventing the interference that may result from electromagnetic wave.

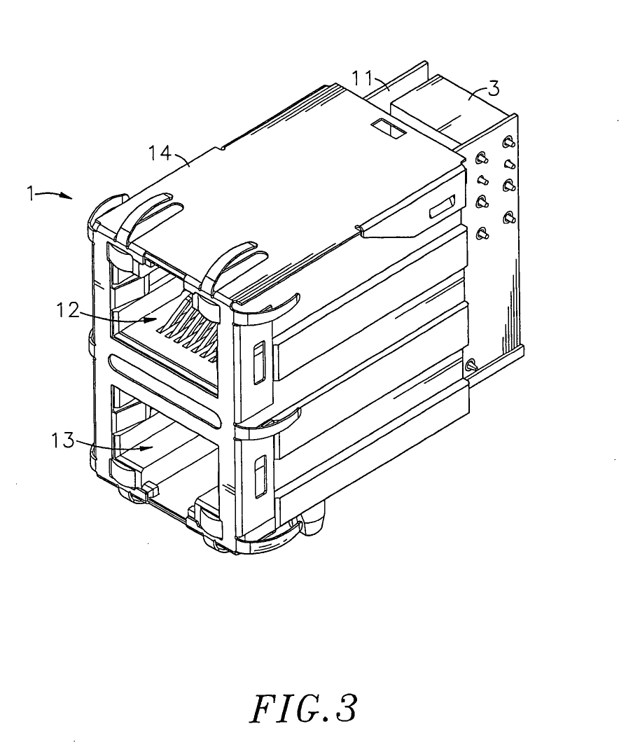

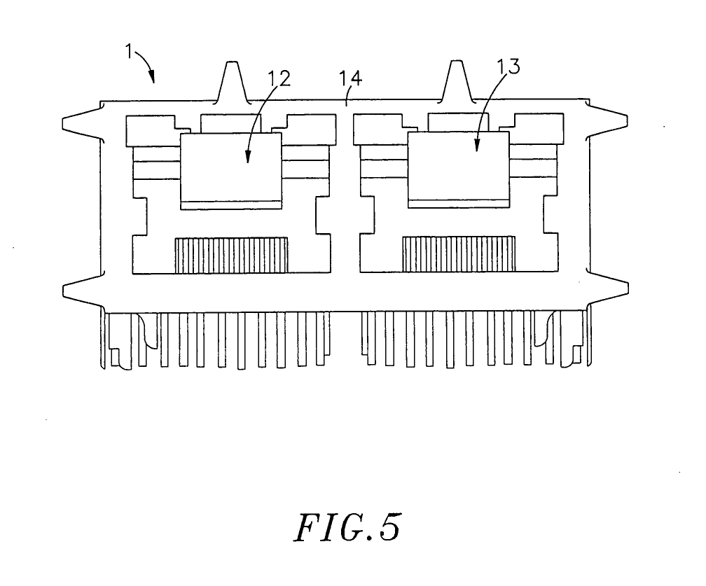

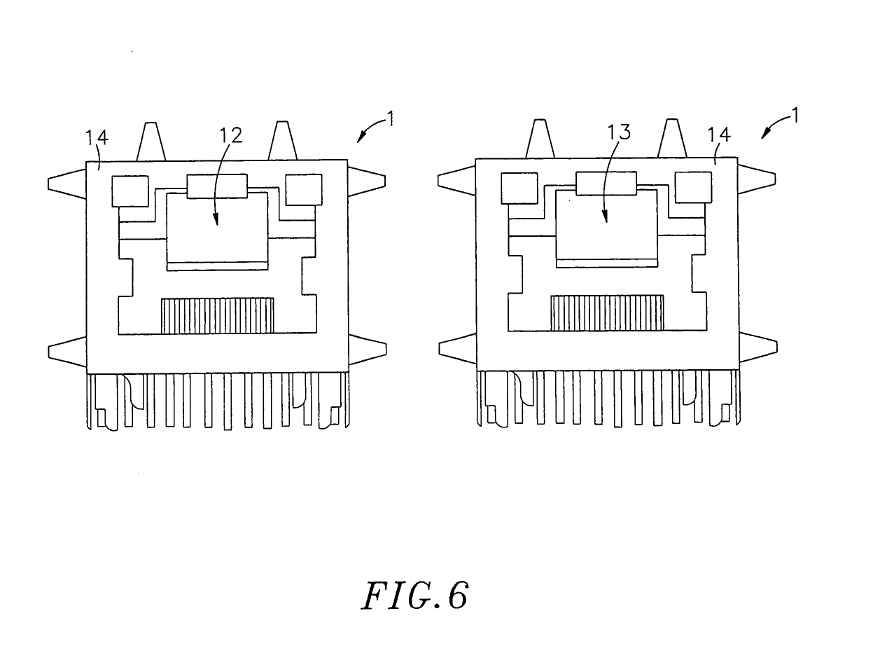

Both the signal input port 12 and the signal output port 13 of the electronic device 1 mentioned above can be the RJ45 connection interface that complies with Ethernet specifications for electrical connection with a variety of external network equipments. In addition, the electronic device 1 may be a network connector, a human-computer interface or any electronic equipment that comprises an input/output control interface. Furthermore, the network connector can comprise a plurality of integrated layers arranged in upper and lower sides or left and right sides (as shown in FIGS. 3 and 5). Alternatively, the network connector can comprises a plurality of detachable layers separately arranged in upper and lower sides or left and right sides (as shown in FIG. 6).

Therefore, the present invention is mainly characterized by installation of at least one signal input port 12 and signal output port 13 in the electronic device 1. The signal input port 12 and the signal output port 13 are connected electrically with the filter module 2 capable of filtering the noise to the external network signals and the automatic diversion device 3 which is electrically connected to the power input device 4. When the power input device 4 fails, the signal diversion component 31 of the automatic diversion device 3 will be in a close-circuit connection status, allowing the external network signals to be inputted from the signal input port 12 and inducted directly into the signal output port 13 for output without being converted through the control chip on the motherboard of the computer host, so as to avoid interruptions of power supply or signals for the electronic device 1 that may occur as a result of short circuit, outage or failure of the power input device 4. In general, the invention has the following benefits and features:

1. The automatic diversion device 3 is electrically connected with the signal input port 12 and the signal output port 13 to form a signal diversion loop. When the power input device 4 fails, the signal diversion component 31 of the automatic diversion device 3 will be in a close-circuit connection status, allowing the external network signals, after being inputted from the signal input port 12, to be outputted directly via the signal output port 13 without being converted by the control chip on the motherboard of the computer host, thus avoiding paralysis of the whole network system that may occur due to interruption of the external network signals and ensuring that the network system can continue to work normally when the power supply to the electronic device 1 is cut off.

2. The signal input port 12, the signal output port 13, the filter module 2 and the automatic diversion device 3 are integrated into the electronic device 1. Such integration can generate such benefits as relatively less space, number and costs needed for separate installation of individual components on the motherboard of the computer host. It also allows the original automatic diversion device 3 installed on the motherboard to be removed, helps simplify configuration of the control circuit, connection interfaces and electronic components on the motherboard, and saves the space for circuit layout effectively.

3. The electronic device 1 is covered with the shield shell 14 and connected with the motherboard of the computer host to form a grounding loop so as to induct and transmit the electromagnetic interferences generated around the electronic device 1 and the noises on the circuit board 11 into the grounding end of the computer host for release, thus effectively preventing the interference that may result from electromagnetic waves.

4. The signal diversion component 31 of the automatic diversion device 3 is installed between the filter module 21 and the signal input port 12 and signal output port 13 of the electronic device 1. Therefore, when the power input device 4 fails, the external network signals will be directly diverted by the automatic diversion device 3 for output instead of being filtered via the filter module 2, thus reducing signal attenuations effectively and securing more stable and precise transmission of signals.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. An automatic network signal diversion mechanism capable of preventing interruptions of power supply and signals, particularly said automatic network diversion mechanism capable of inducting external network signals directly to prevent interruptions of power supply and signals, comprising an electronic device and an automatic diversion device; wherein:
said electronic device comprises a circuit board which mounts a plurality of electronic components, at least one filter module, an automatic diversion device and a circuit layout thereon, and said circuit board is equipped with at least one signal input port and signal output port; and
said automatic diversion device is electrically connected with said signal input port and said signal output port, and can be connected electrically with a power input device; when said power input device fails, said automatic diversion device is in a close-circuit connection status, allowing said external network signals inputted from said signal input port to be outputted directly via said signal output port.

2. The automatic network signal diversion mechanism capable of preventing interruptions of power supply and signals according to claim 1, wherein said filter module is electrically connected with said signal input port and said signal output port respectively to further enable electrical connection with a data processing unit on a motherboard of a computer host for filtering noises in said external network signals.

3. The automatic network signal diversion mechanism capable of preventing interruptions of power supply and signals according to claim 2, wherein said filter module may comprise a resistor, a capacitor or other passive components and a transformer.

4. The automatic network signal diversion mechanism capable of preventing interruptions of power supply and signals according to claim 2, wherein said data processing unit at least comprises an Ethernet control chip (PHY IC Chip) and an oscillator, and said control chip can convert external network WAN signals inputted from said signal input port into LAN signals and then output said LAN signals via said signal output port.

5. The automatic network signal diversion mechanism capable of preventing interruptions of power supply and signals according to claim 1, wherein said automatic diversion device comprises a signal diversion component, and said signal diversion component may be a relay, signal switcher or any electronic component with input/output control functions.

6. The automatic network signal diversion mechanism capable of preventing interruptions of power supply and signals according to claim 1, wherein said power input device may be a power supply or battery installed on a motherboard of a computer host to provide the needed electricity.

7. The automatic network signal diversion mechanism capable of preventing interruptions of power supply and signals according to claim 1, wherein said power input device may be a uninterruptable power supply (UPS) or battery installed external.

8. The automatic network signal diversion mechanism capable of preventing interruptions of power supply and signals according to claim 1, wherein said electronic device is covered with a shield shell, and said shield shell is connected with a motherboard of a computer host to form a grounding loop, so as to induct and transmit electromagnetic interferences generated around said electronic device and noises on said circuit board into the grounding end of said computer host for release.

9. The automatic network signal diversion mechanism capable of preventing interruptions of power supply and signals according to claim 1, wherein said signal input port and said signal output port of said electronic device may be RJ45 interfaces that comply with Ethernet specifications.

10. The automatic network signal diversion mechanism capable of preventing interruptions of power supply and signals according to claim 1, wherein said electronic device can be a network connector, human-computer interface or any electronic equipment with input/output control interface.

11. The automatic network signal diversion mechanism capable of preventing interruptions of power supply and signals according to claim 10, wherein said network connector comprises a plurality of integrated layers equally arranged in upper and lower sides or left and right sides.

12. The automatic network signal diversion mechanism capable of preventing interruptions of power supply and signals according to claim 10, wherein said network connector comprises a plurality of detachable layers separately arranged in upper and lower sides or left and right sides.
